(19) United States
(12) Patent Application Publication
(10) Pub. No.: US 2012/0228784 A1
(43) Pub. Date: Sep. 13, 2012

(54) SEMICONDUCTOR DEVICE

(76) Inventor: Tatsu Suzuki, Shinagawa-ku (JP)

(21) Appl. No.: 13/510,734

(22) PCT Filed: Nov. 11, 2010
(86) PCT No.: PCT/JP2010/006617

§ 371 Date: May 18, 2012

(30) Foreign Application Priority Data
Nov. 19, 2009 (JP) 2009-263702

(51) Int. Cl. H01L 23/29

(52) U.S. Cl. 257/792; 257/E23.119

(57) ABSTRACT

Disclosed is a semiconductor device configured by encapsulating a semiconductor element, partially or entirely covered with a polyimide, using an epoxy resin composition for encapsulating semiconductor device which contains an epoxy resin (A), a phenol resin (B), a curing accelerator (C), an inorganic filler (D), and a silane coupling agent (E) represented by the formula (1):

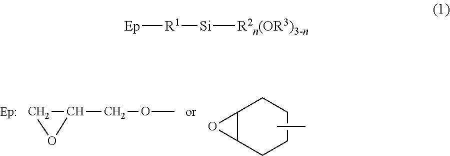

(in the formula (1), each of R¹, R² and R³ represents a C₁₋₄ hydrocarbon group, all of them may be the same or different from each other, and n represents an integer from 0 to 2), and/or a hydrolytic condensate thereof.

### TECHNICAL FIELD

The present invention relates to a semiconductor device, and in particular to an area mounting-type semiconductor device having, mounted on one surface of a printed wiring board or metal lead frame, a semiconductor element partially or entirely covered with a polyimide, and being encapsulated with a resin only on the mounting surface.

### BACKGROUND ART

In recent market trends directed to dimensional shrinkage, weight reduction and higher performances of electronic instruments, semiconductor elements have been more densely integrated year by year, with an increasing opportunity for surface mounting of semiconductor devices. In this situation, surface mounting-type semiconductor devices have newly been developed, and have gradually replacing those of conventional structure. With the advance of dimensional shrinkage and thinning of semiconductor devices, epoxy resin composition for encapsulating semiconductor device has been requested to further decrease the viscosity and to increase the strength. From the environmental point of view, the epoxy resin composition for encapsulating semiconductor device is also requested to be flame retardant, without using flame retarder such as bromine compound or antimony oxide. In addition, in the process of mounting of the semiconductor devices, there has been an increasing trend of using lead-free solder having higher melting point than that of conventional solders. Due to adoption of the solder, mounting temperature need to be elevated by approximately 20° C. than in the conventional process, and this considerably degrades reliability of the semiconductor device after being mounted, as compared with the current situation.

BGA (ball grid array), and CSP (chip scale package) in pursuit of further shrinkage, are the representatives of the area mounting-type semiconductor devices. They have been developed for coping with requirements for larger number of pins and higher operational speed, which have been becoming almost impossible to be satisfied by the conventional surface mounting-type semiconductor devices represented by QFP (quad flat package), SOP (small outline package) and so forth. This sort of area mounting-type semiconductor device may be obtained by mounting a semiconductor element on one surface of a hard circuit board represented by BT resin/copper foil circuit board (bismaleimide-triazine resin/glass fabric reinforced substrate), or flexible circuit board represented by polyimide resin film/copper metallized circuit board, and by molding and encapsulating the surface having the semiconductor element mounted thereon, that is, only one surface of the substrate using an epoxy resin composition or the like. On the other surface of the substrate, opposite to the surface having the semiconductor element mounted thereon, solder balls are formed so as to be arranged in a two dimensional manner, to thereby establish connection to the circuit substrate on which the semiconductor device is mounted. Still another substrate for mounting thereon the semiconductor element, other than the organic material-based substrate described in the above, includes metal substrate such as lead frame.

The area mounting-type semiconductor device is given in the form of one-side encapsulating in which only the surface having the semiconductor element mounted thereon is encapsulated with an epoxy resin composition, while leaving the surface having the solder balls formed thereon un-encapsulated. Although the metal substrate such as lead frame might have a encapsulating resin layer of several tens of micrometers also on the surface having the solder balls formed thereon, this may substantially be understood as the one-side encapsulating, since a encapsulating resin layer having a thickness of several hundreds of micrometers to several millimeters is formed over the surface having the semiconductor element mounted thereon.

For the case where the area mounting-type semiconductor device is soldered by solder processes such as infrared radiation reflow, vapor phase soldering and solder dipping, separation would occur at the interface between the surface of organic substrate having the semiconductor element mounted thereon and the cured epoxy resin composition, due to stress ascribable to abrupt vaporization, under high temperatures, of moisture retained in the semiconductor device, incorporated as a result of moisture absorption by the cured epoxy resin composition and organic substrate. Accordingly, there has been a need for a technique of satisfying soldering resistance of the epoxy resin composition for encapsulating area mounting-type semiconductor device.

Some semiconductor elements are covered with a polyimide film over the surface thereof, for the purpose of relaxing stress between the encapsulating resin and the element, and a ray shielding. In this context, a technique of making the polyimide resin per se photo-sensitive has attracted attention. The photo-sensitive polyimide resin is capable of not only simplifying pattern forming process as compared with the case of using a non-photo-sensitive polyimide resin, but also disusing a highly toxic etching solution, and is therefore advantageous in terms of safety and environmental preservation. Photo-sensitization of the polyimide resin is therefore expected to be an important technique.

On the other hand, the polyimide film is unfortunately less adhesive to the encapsulating resin. Reason why the polyimide film is less adhesive to the encapsulating resin is supposed that chemical bond between the polyimide film and the encapsulating resin is weak, or that only a limited degree of anchoring effect is available due to smoothness of the surface of the polyimide film. As for the polyimide resin given with photo-sensitivity, it is also supposed that an additive for imparting photo-sensitivity, for example, may inhibit close adhesiveness to the encapsulating resin.

A known technique for improving the close adhesiveness between the polyimide film and the encapsulating resin is typically such as subjecting the surface of the polyimide film to plasma treatment, followed by resin encapsulating. According to a proposal regarding the technique, irregularity is produced on the surface of the polyimide film enough to increase the close adhesiveness with the encapsulating material, and thereby the reliability may be improved (see Patent Document 1, for example). The effect of surface modification given by the plasma treatment is, however, less sustainable, and is gradually lost with the elapse of time after the plasma treatment. Moreover, the plasma treatment per se is a factor of increasing the number of processes.

Another proposal has been made on provision of a polyimide film mixed with crushed filler, over a cover film which covers the top surface of the semiconductor element. Since the surface above the semiconductor element is roughened with notable irregularities, the surface area of the polyimide resin increases enough to improve the close adhesiveness with the epoxy resin, with an additional effect preventing cracks by virtue of dispersion of stress at saw tooth-like portions of the irregular profile (see Patent Document 2, for example). The method is, however, not satisfactory since the crushed filler may damage the cover film. There has been still another proposal for solving the problem, such as providing the polyimide film on the cover film, and further providing thereon a polyimide film mixed with the crushed filler. The method undesirably increases the number of processes.

Still another proposal has been made so as to improve the close adhesiveness of the encapsulating resin by preliminarily adding thereto a solvent capable of dissolving the polyimide-based resin, to thereby improve the reliability (see Patent Document 3, for example). Dissolution of the polyimide-based resin is, however, against the purpose of provision of the polyimide film aimed at relaxing stress between the encapsulating resin and the element, and shielding the element from a ray ascribable to the encapsulating resin.

In this situation, there has been an accelerating demand for improved reliability of the semiconductor device, by imparting the epoxy resin composition with an improved close adhesiveness with the polyimide film.

### RELATED DOCUMENT

### Patent Document

[Patent Document 1] Japanese Laid-Open Patent Publication No. H08-153833
[Patent Document 2] Japanese Laid-Open Patent Publication No. H06-204362
[Patent Document 3] Japanese Laid-Open Patent Publication No. H05-275573

### DISCLOSURE OF THE INVENTION

The present invention is aimed at solving the above-described problems, and the object of which is to provide a semiconductor device which ensures excellent close adhesiveness between the encapsulating resin and the polyimide film which covers the surface of the semiconductor element, and excellent soldering resistance.

The present inventor found out that the above-described problems may be solved and a semiconductor device well matched to the object may be obtained, by encapsulating the semiconductor element, covered with a polyimide, using an epoxy resin composition containing a silane coupling agent having a specific structure, and reached the present invention.

According to the present invention, a semiconductor device capable of ensuring excellent close adhesiveness between the encapsulating resin and the polyimide film which covers the surface of the semiconductor element, and excellent in the soldering resistance, may be obtained. The present invention is therefore useful for semiconductor device having the polyimide film which covers the semiconductor element, and in particular useful for area mounting-type semiconductor device and so forth.

According to the present invention, there is provided a semiconductor device configured by encapsulating a semiconductor element, partially or entirely covered with a polyimide, using an epoxy resin composition for encapsulating semiconductor device which contains an epoxy resin (A), a phenol resin (B), a curing accelerator (C), an inorganic filler (D), and a silane coupling agent (E) represented by the formula (1):

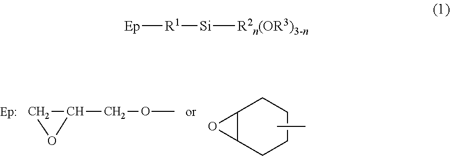

(in the formula (1), each of R¹, R² and R³ represents a C₁₋₄ hydrocarbon group, all of them may be the same or different from each other, and n represents an integer from 0 to 2), and/or a hydrolytic condensate thereof.

According to one embodiment of the present invention, in the above-described semiconductor device, the silane coupling agent (E) and/or the hydrolytic condensate thereof are a silane coupling agent represented by the formula (2) below:

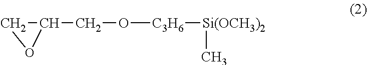

and/or a hydrolytic condensate thereof.

According to one embodiment of the present invention, in the above-described semiconductor device, ratio of the silane coupling agent (E) and/or the hydrolytic condensate thereof accounts for 0.01 to 1.0% by mass of the whole epoxy composition for encapsulating semiconductor device.

According to one embodiment of the present invention, in the above-described semiconductor device, the epoxy resin (A) contains an epoxy resin represented by the formula (3) below:

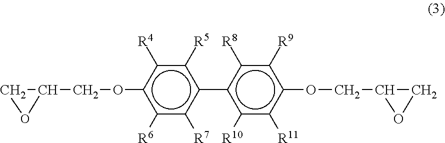

(in the formula (3), each of R⁴ to R¹¹ is selected from a hydrogen atom and C₁₋₄ alkyl group, all of them may be the same or different from each other).

According to one embodiment of the present invention, in the above-described semiconductor device, the phenol resin (B) contains a phenol resin represented by the formula (4):

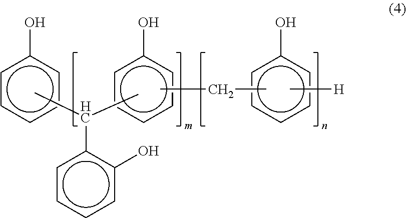

(in the formula (4), m represents an integer from 1 to 5, and n represents an integer from 0 to 5).

According to one embodiment of the present invention, in the above-described semiconductor device, the polyimide is obtained by dealcoholization of a polyimide precursor represented by the formula (5):

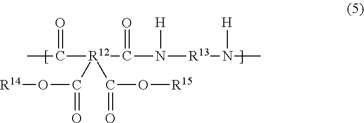

(in the formula (5), R¹² is an organic group having at least two carbon atoms, R¹³ is an organic group having at least two carbon atoms, each of R¹⁴ and R¹⁵ is an organic group having at least one double bond, all of them may be the same or different from each other).

According to one embodiment of the present invention, in the above-described semiconductor device, R¹², R¹³, R¹⁴ and R¹⁵ of the polyimide precursor represented by the formula (5) are groups represented by the formula (6) below:

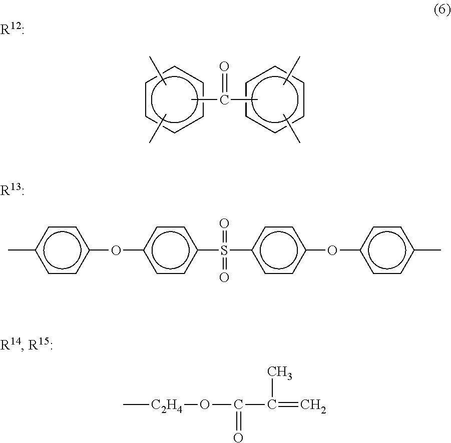

According to one embodiment of the present invention, there is provided a semiconductor device configured as an area mounting-type semiconductor device, having the semiconductor element mounted on one surface of a substrate, and only the surface of the substrate having the semiconductor element mounted thereon being encapsulated with the epoxy resin composition for encapsulating semiconductor device.

According to one embodiment of the present invention, there is provided a semiconductor device configured as a board-on-chip type semiconductor device, having the semiconductor element mounted on one surface of a substrate having an opening, and the surface of substrate having the semiconductor element mounted thereon and the opening being encapsulated with the epoxy resin composition for encapsulating semiconductor device.

According to the present invention, a semiconductor device capable of ensuring excellent close adhesiveness between the encapsulating resin and the polyimide film which covers the surface of the semiconductor element, and excellent in the soldering resistance, may be obtained.

### BRIEF DESCRIPTION OF THE DRAWING

FIG. 1 is a drawing illustrating a cross-sectional structure of an exemplary semiconductor device of the one-side encapsulating type, configured using the resin composition for encapsulating semiconductor device of the present invention.

### DESCRIPTION OF THE EMBODIMENTS

The semiconductor device of the present invention is characteristically obtained by encapsulating a semiconductor element, partially or entirely covered with a polyimide, using an epoxy resin composition for encapsulating semiconductor device which contains an epoxy resin (A), a phenol resin (B), a curing accelerator (C), an inorganic filler (D), and a silane coupling agent (E) represented by the formula the formula (1), and/or a compound obtained by hydrolyzing and poly-condensing it (hydrolytic condensate). Distinctive effects achieved by the thus-configured present invention include that close adhesiveness between the encapsulating resin and the polyimide film which covers the surface of the semiconductor element may be enhanced, and that high reliability such as soldering resistance may be achieved in particular in the area-mounted semiconductor device. The present invention will be detailed below.

To begin with, the polyimide and the precursor thereof, which are constituent of the semiconductor device in the present invention, will be detailed. The polyimide is generally obtained by dealcoholization or dehydration of its precursor. The polyimide is classified into photosensitive polyimide and non-photosensitive polyimide, and the photosensitive polyimide is further classified into ester bond-type polyimide and ionic bond-type polyimide. The polyimide used for the semiconductor device of the present invention is not specifically limited, and may typically be a polyimide obtained by dealcoholizing a photosensitive resin composition which contains a polyimide precursor as a major constituent. The polyimide precursor is not specifically limited, and may typically be a polyimide precursor represented by the formula (5).

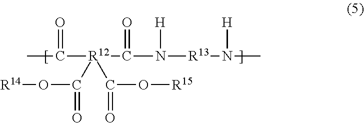

(In the formula (5), R¹² represents an organic group having at least two carbon atoms, R¹³ represents an organic group having at least two carbon atoms, each of R¹⁴ and R¹⁵ represents an organic group having at least one double bond, all of them may be the same or different from each other).

R¹² in the formula (5) represents an organic group having at least two carbon atoms. R¹² is introduced from a compound having an organic group. If R¹² is a group containing an aromatic ring or an aromatic heterocycle, the resultant polyimide will have heat resistance. Preferable examples of R¹² include 3,3′,4,4′-benzophenone tetracarboxylic acid residue, pyromellitic acid residue, and 4,4′-oxydiphthalic acid residue, but not limited thereto. Among them, 3,3′,4,4′-benzophenone tetracarboxylic acid residue is preferable from the viewpoint of heat resistance of the resultant polyimide. They may be used alone or in combination of two or more species.

In the formula (5), R¹³ is an organic group having at least two carbon atoms. R¹³ is introduced from a compound having an organic group. Similarly to R¹², from the viewpoint of heat resistance of the resultant polyimide, R¹³ is preferably a group having an aromatic ring or an aromatic heterocycle. Specific and preferable examples of R¹³ include bis[4-(4-aminophenoxy)phenyl]solfone residue, bis[4-(3-aminophenoxy)phenyl]solfone residue, 4,4′-diaminodiphenyl solfone residue, 3,3′-diaminodiphenyl solfone residue, 4,4′-bis[4-(4-aminophenoxy)phenoxy]diphenyl solfone residue, 4,4′-diamide diphenyl sulfide residue, 4,4′-diaminodiphenyl ether residue, and p-phenylenediamine residue, but not limited thereto. Among them, bis[4-(4-aminophenoxy)phenyl] solfone residue is preferable from the viewpoint of heat resistance of the resultant polyimide. They may be used alone or in combination of two or more species.

In the formula (5), each of R¹⁴ and R¹⁵ independently represents an organic group having at least one double bond, and preferably a photosensitive group having one to three acryl (methacryl) groups. Compounds used for introducing R¹⁴ and R¹⁵ include 2-hydroxyethyl methacrylate, 2-hydroxyethyl acrylate, glycidyl methacrylate, glycidyl acrylate, 2-hydroxypropyl methacrylate, 2-hydroxypropyl acrylate, pentaerythrytol triacrylate, pentaerythrytol trimethacrylate, pentaerythrytol acrylate dimethacrylate, pentaerythrytol diacrylate methacrylate, glycerol diacrylate, glycerol dimethacrylate, glycerol acrylate methacrylate, trimethylolpropane diacrylate, 1,3-diacryloylethyl-5-hydroxyethylisocyanurate, 1,3-dimethacrylate-5-hydroxyethylisocyanurate, ethylene glycol-modified pentaerythritol triacrylate, propylene glycol-modified pentaerythrytol triacrylate, trimethylolpropane diacrylate, trimethylolpropane dimethacrylate, polyethylene glycol-modified methacrylate, polyethylene glycol-modified acrylate, polypropylene glycol-modified acrylate, and polypropylene glycol-modified methacrylate, but not limited thereto. Among them, 2-hydroxyethyl methacrylate is preferable from the viewpoint of reactivity. They may be used alone or in combination of two or more species.

Among them, compounds having the groups listed below for R¹² to R¹⁵ in the formula (5) are preferable.

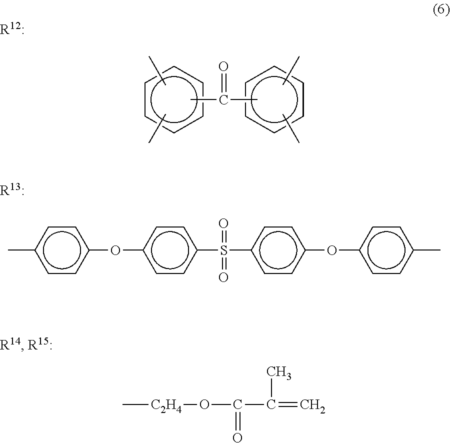

Methods of producing the polyimide precursor (5) may be any of publicly known ones, without special limitation. One exemplary method of producing polyimide is as follows. A compound having alcohol groups for introducing the photosensitive groups R¹⁴, R¹⁵ is dissolved into a solvent, an excessive amount of an acid anhydride or a derivative thereof is allowed to react therewith, and the residual carboxyl groups and acid anhydride groups are allowed to react with a diamine. The photosensitive polyimide composition containing the polyimide may be added with photo-sensitizer, initiator, storability improver, adhesive auxiliary, inhibitor, leveling agent, and various fillers, for the purpose of improving lithographic characteristics such as sensitivity and resolution.

Methods of covering the semiconductor element with the photosensitive polyimide composition may be any of publicly known ones, without special limitation. One exemplary method of coating is as follows. First, a photosensitive polyimide composition is coated on an appropriate support, such as silicon wafer, ceramic substrate, aluminum substrate or the like. Methods of coating adoptable herein include spin coating using a spinner, spray coating using a spray coater, dipping, printing, and roll coating. Thickness of coating may be adjustable depending on means of coating, solid concentration of the composition, and viscosity, generally in the range from 1 to 30 μm. Next, the coated film is dried by pre-baking at low temperatures ranging from 60 to 80° C., and is then irradiated with chemical beam according to a desired pattern. The chemical beam adoptable herein includes X-ray, electron beam, ultraviolet radiation, visible light and so forth, preferably having a wavelength of 200 to 500 nm. Next, the unirradiated portion is removed by dissolving it into a developing solution, to thereby obtain a relief pattern. The developing solution adoptable herein includes N-methyl-2-pyrrolidone, N,N-dimethylacetamide, N,N-dimethylformamide, methanol, xylene, isopropanol, water, and alkali aqueous solution, and they may be used alone or in combination of two or more species. Methods of development adoptable herein include those making use of spraying, puddle formation, dipping, ultrasonic wave and so forth. Next, the relief pattern obtained by the development is rinsed with a rinsing solution. The rinsing solution adoptable herein includes methanol, xylene, ethanol, isopropanol, butyl acetate and water. Next, the relief pattern is annealed to form imide ring, to thereby obtain a final pattern excellent in heat resistance. Annealing temperature is preferably 70 to 450° C., and more preferably 150 to 400° C.

The semiconductor element partially or entirely covered with the polyimide in the context of the present invention also includes the case where, for example, the polyimide is removed on electrode pads, through which electrical connection with the external is established, so as to expose them.

Next, the epoxy resin composition for encapsulating semiconductor device, used for the semiconductor device of the present invention, will be detailed. The epoxy resin composition for encapsulating semiconductor device of the present invention contains an epoxy resin (A), a phenol resin (B), a curing accelerator (C), an inorganic filler (D), and a silane coupling agent (E) represented by the formula (1) and/or a hydrolytic condensate.

The epoxy resin (A) adoptable to the epoxy resin composition for encapsulating semiconductor device of the present invention is not specifically limited, and examples of which include crystalline epoxy resin such as biphenyl-type epoxy resin, bisphenol A-type epoxy resin, and bisphenol F-type epoxy resin; novolac-type epoxy resin such as phenol novolac-type epoxy resin, and cresol novolac-type epoxy resin; multi-functional epoxy resin such as triphenol methane-type epoxy resin, and alkyl modified triphenol methane-type epoxy resin; aralkyl-type epoxy resin such as phenol aralkyl-type epoxy resin having a phenylene skeleton, phenol aralkyl-type epoxy resin having a biphenylene skeleton, and naphthol aralkyl-type epoxy resin having a phenylene skeleton; epoxy resin having a naphthalene skeleton such as naphthol novolac-type epoxy resin, and dihydroxynaphthalene-type epoxy resin; epoxy resin having a triazine nucleus such as triglycidyl isocyanurate, and monoallyl diglycidyl isocyanurate; and bridged cyclic hydrocarbon compound-modified, phenol-type epoxy resin such as dicyclopentadiene-modified, phenol-type epoxy resin. They may be used alone or in combination of two or more species.

Among them, biphenyl-type epoxy resin represented by the formula (3) is preferable as the epoxy resin (A), and epoxy resin having a methyl group for each of R⁴, R⁶, R⁹ and R¹¹ in the formula (3), and a hydrogen atom for each of R⁵, R⁷, R⁸ and R¹⁰ is more preferable. This sort of epoxy resin has a low viscosity, and may therefore contain a large amount of filler, to thereby reduce water absorption rate of the epoxy resin. In addition, since they are bifunctional and has a highly heat-resistant skeleton, soldering resistance may further be improved.

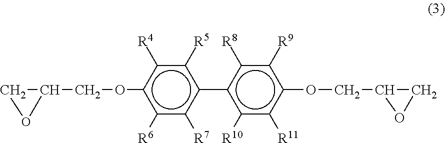

(In the formula (3), each of R⁴ to R¹¹ is selected from hydrogen atom, and C₁₋₄ alkyl group, and may be the same or different from each other).

The phenol resin (B) adoptable to the epoxy resin composition for encapsulating semiconductor device of the present invention is not specifically limited, and examples of which include novolac-type resin such as phenol novolac resin, and cresol novolac resin; multi-functional phenol resin such as triphenol methane-type resin, and copolymer of triphenol methane-type and phenol novolac-type resins; aralkyl-type resin such as phenol aralkyl-type phenol resin (having phenylene skeleton or biphenylene skeleton), and naphthol aralkyl resin; and modified phenol resin such as terpene-modified phenol resin, and dicyclopentadiene-modified phenol resin. They may be used alone or in combination of two or more species.

Among them, the multi-functional phenol resin represented by the formula (4) is preferable as the phenol resin (B). By using this sort of multi-functional phenol resin, warping characteristics of the area mounting-type semiconductor device may be improved, and thereby the soldering resistance may further be improved.

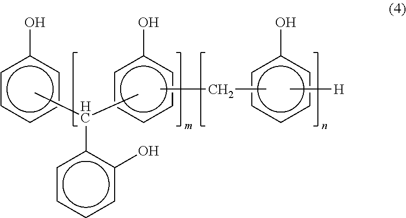

(In the formula (4), m represents an integer from 1 to 5, and n represents an integer from 0 to 5).

Equivalence ratio (EP/OH) of the number of epoxy groups (EP) of the whole epoxy resin and the number of phenolic hydroxy groups (OH) of the whole phenol resin used for the epoxy resin composition for encapsulating semiconductor device of the present invention is preferably 0.5 or larger and 2 or smaller, and particularly preferably 0.7 or larger and 1.5 or smaller. By adjusting the equivalence ratio in the above-described ranges, the moisture resistance and the curability may be prevented from degrading.

Examples of the curing accelerator (C) adoptable to the epoxy resin composition for encapsulating semiconductor device of the present invention include diazabicycloalkene and its derivative such as 1,8-diazabicyclo[5.4.0]undecene-7; organic phosphine such as triphenylphosphine, methyldiphenylphosphine; tetra-substituted phosphonium/tetra-substituted borate such as tetraphenyl phosphonium/tetraphenyl borate, tetraphenylphosphonium/tetrabenzoic acid borate, tetraphenylphosphonium/tetranaphthoic acid borate, tetraphenylphosphonium/tetranaphthoyloxy borate, and tetraphenylphosphonium/tetranaphthyloxy borate; and adduct of phosphine compound and quinone compound. They may be used alone or in combination of two or more species.

The inorganic filler (D) adoptable to the epoxy resin composition for encapsulating semiconductor device of the present invention may be any of those generally used as epoxy resin composition for encapsulating semiconductor device. Examples of the inorganic filler (D) include fused spherical silica, fused crushed silica, crystalline silica, talc, alumina, titanium white and silicon nitride, among which fused spherical silica is most preferably used. These inorganic fillers may be used alone or in combination of two or more species. They may be surface-treated with a coupling agent. The inorganic filler (D) preferably has a geometry possibly closest to true sphere and has a broad grain size distribution, in view of improving the fluidity. Content of the inorganic filler (D) used in the present invention is 83% by mass or more and 95% by mass or less of the total epoxy resin composition, and more preferably 87% by mass or more and 93% by mass or less. By adjusting the content of the organic filler (D) within the above described ranges, the resultant resin composition will have low hygroscopicity, low thermal expansion, sufficient soldering resistance, and good warping characteristics, while also successfully suppressing degradation of fluidity, incomplete filling during molding, and deformation of gold wires in the semiconductor device due to high viscosity.

The epoxy resin composition for encapsulating semiconductor device of the present invention contains silane coupling agent (E) represented by the formula (1):

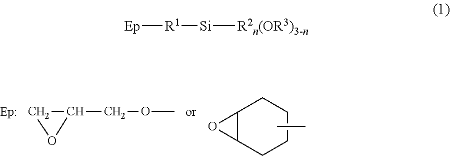

(In the formula (1), each of R¹, R² and R³ represents a C₁₋₄ hydrocarbon group, all of them may be the same or different from each other. n represents an integer from 0 to 2) and/or hydrolytic condensate thereof.

Examples of the silane coupling agent include
(γ-glycidoxypropyl)trimethoxysilane,
(γ-glycidoxypropyl)methyldimethoxysilane,
(γ-glycidoxypropyl)dimethylmethoxysilane,
(γ-glycidoxypropyl)triethoxysilane,
(γ-glycidoxypropyl)methyldiethoxysilane,
(γ-glycidoxypropyl)dimethylethoxysilane,
(γ-glycidoxypropyl)ethyldimethoxysilane,
(γ-glycidoxypropyl)diethylmethoxysilane,
(γ-glycidoxypropyl)ethyldiethoxysilane,
(γ-glycidoxypropyl)diethylethoxysilane,
γ-(2,3-epoxycyclohexyl)propyltrimethoxysilane,
γ-(2,3-epoxycyclohexyl)propylmethyldimethoxysilane,
γ-(2,3-epoxycyclohexyl)propyldimethylmethoxysilane,
γ-(2,3-epoxycyclohexyl)propyltriethoxysilane,
γ-(2,3-epoxycyclohexyl)propylmethyldiethoxysilane,
γ-(2,3-epoxycyclohexyl)propyldimethylethoxysilane,
γ-(2,3-epoxycyclohexyl)propylethyldimethoxysilane,
γ-(2,3-epoxycyclohexyl)propyldiethylmethoxysilane,
γ-(2,3-epoxycyclohexyl)propylethyldiethoxysilane,
γ-(2,3-epoxycyclohexyl)propyldiethylethoxysilane,
γ-(3,4-epoxycyclohexyl)propyltrimethoxysilane,
γ-(3,4-epoxycyclohexyl)propylmethyldimethoxysilane,
γ-(3,4-epoxycyclohexyl)propyldimethylmethoxysilane,
γ-(3,4-epoxycyclohexyl)propyltriethoxysilane,
γ-(3,4-epoxycyclohexyl)propylmethyldiethoxysilane,
γ-(3,4-epoxycyclohexyl)propyldimethylethoxysilane,
γ-(3,4-epoxycyclohexyl)propylethyldimethoxysilane, γ-(3,4-epoxycyclohexyl)propyldiethylmethoxysilane,
γ-(3,4-epoxycyclohexyl)propylethyldiethoxysilane, and
γ-(3,4-epoxycyclohexyl)propyldiethylethoxysilane. Also compounds, obtained by hydrolyzing the silane coupling agent and by poly-condensing the hydrolysate, may be adoptable. These compounds may be used alone, or in combination of two or more species.

Among them, preferable is a hydrolytic condensate, which is a compound obtained by hydrolzing the silane coupling agent represented by the formula (2) below, and by poly-condensing the hydrolysate. By using the compound, the soldering resistance may be improved as a result of improvement in the close adhesiveness with the polyimide film, even if the epoxy resin composition for encapsulating semiconductor device, containing a resin less durable to soldering, such as a combination of biphenyl-type epoxy resin and phenol novolac resin, were used.

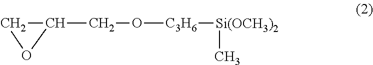

Methods of hydrolyzing the silane coupling agent is not specifically limited. An acidic or basic catalyst may be used for the purpose of accelerating the hydrolytic reaction. Examples of the catalyst include protonic acid such as formic acid and acetic acid; Lewis acid such as aluminum chloride, and iron chloride; and basic catalyst such as triphenyl phosphine, and 1,8-diazabicyclo[5.4.0]undecene-7 (DBU).

Ratio of the silane coupling agent (E) and/or the hydrolytic condensate thereof relative to the total composition is preferably 0.01 to 1.0% by mass, and more preferably 0.1 to 0.5% by mass. By adjusting the content of the silane coupling agent (E) and/or the hydrolytic condensate thereof within the above-described ranges, the resultant resin composition will have an improved close adhesiveness with the polyimide film, and a good soldering resistance, while successfully suppressing non-conformities such as degradation in the mechanical strength.

In the present invention, other silane coupling agents may be used therewith, so long as they will not impair the effects of the silane coupling agent (E) and/or the hydrolytic condensate thereof. The silane coupling agent possibly used therewith is not specifically limited, and examples of which include silane coupling agent such as mercaptosilane, aminosilane, alkylsilane, ureidosilane, and vinylsilane; and coupling agent such as titanate coupling agent, aluminum coupling agent, and aluminum/zirconium coupling agent.

Besides the above-described ingredients (A) to (E), various additives may appropriately be added to the epoxy resin composition for encapsulating semiconductor device of the present invention, depending on needs. Examples of the additives include mold releasing agent including natural wax such as carnauba wax, synthetic wax such as polyethylene wax, higher aliphatic acid and metal salt thereof such as stearic acid and zinc stearate, and paraffin; colorant such as carbon black and red iron oxide; flame retarder such as brominated epoxy resin, antimony trioxide, aluminum hydroxide, magnesium hydroxide, zinc borate, zinc molybdate, and phosphazene; inorganic ion exchanger such as bismuth oxide hydrate; and antioxidant.

The epoxy resin composition for encapsulating semiconductor device of the present invention is adjustable in terms of dispersibility, fluidizing characteristics and so forth, by mixing the ingredients (A) to (F), and other additives if necessary, typically by using a mixer or the like at normal temperature, and by kneading under heating using a kneader such as roll kneader, extruder or the like, followed by cooling and crushing.

Next, the semiconductor device of the present invention will be detailed. The semiconductor device of the present invention may be obtained by encapsulating an electronic component such as the semiconductor element using the above-described epoxy resin composition for encapsulating semiconductor device, and by curing the resin by a conventional molding method such as transfer molding, compression molding, injection molding or the like. Other aspects of the method of manufacturing of the semiconductor device may be any of the publicly-known methods. The semiconductor device may be obtained also by integrally encapsulating and molding a plurality of semiconductor elements, and then individualizing them.

Examples of the semiconductor element to be encapsulated include integrated circuit, large-scale integrated circuit, transistor, thyristor, diode, and solid imaging device, but not limited thereto.

Examples of the resultant semiconductor device include dual inline package (DIP), plastic-leaded chip carrier (PLCC), quad flat package (QFP), low profile quad flat package (LQFP), small outline package (SOP), small outline J-lead package (SOJ), thin small outline package (TSOP), thin quad flat package (TQFP), tape carrier package (TCP), ball grid array (BGA), chip size package (CSP), and board-on-chip (BOC) package, but not limited thereto. Examples of the semiconductor device obtained after being encapsulated and molding using the resin composition for encapsulating semiconductor device, and being individualzed, include MAP-type ball grid array (BGA), MAP-type chip size package (CSP), and MAP-type quad flat non-lead (QFN).

The semiconductor device, having the semiconductor element encapsulated therein by a molding method such as transfer molding using resin composition for encapsulating semiconductor device, is allowed to stand as it is, or at around a temperature of 80° C. to 200° C. or around, for approximately 10 minutes to 10 hours so as to completely cure the resin composition, and is then mounted to an electronic instrument or the like.

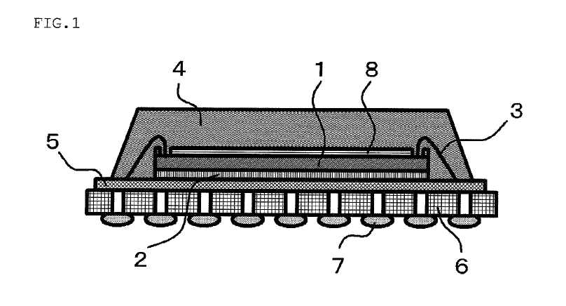

FIG. 1 is a drawing illustrating a cross-sectional structure of an exemplary semiconductor device of the one-side encapsulating type, configured using the resin composition for encapsulating semiconductor device of the present invention. A solder resist 5 is provided to the surface of a substrate 6 so as to be stacked thereon, and a semiconductor element 1 preliminarily covered with a polyimide film 8 is fixed on the solder resist 5 while placing a cured die-bonding material 2 in between. Portions of the polyimide film 8 on electrode pads of the semiconductor element 1 and portions of the solder resist 5 on electrode pads of the substrate 6 are removed by development, so as to expose the electrode pads, in order to establish electronic contact between the semiconductor element 1 and the substrate 6. The semiconductor device illustrated in FIG. 1 is, therefore, designed to connect the electrode pads of the semiconductor element 1 and the electrode pads on the substrate 6 by bonding wires 3. By encapsulating the semiconductor device using the epoxy resin composition for encapsulating semiconductor device so as to form a cured article 4, the semiconductor device encapsulated only on one surface of the substrate 6, having the semiconductor element 1 mounted thereon, may be obtained. The electrode pads on the substrate 6 are connected internally through the substrate 6 to solder balls 7 arranged on the non-encapsulated surface.

### EXAMPLE

The present invention will be explained below referring to Examples, without being limited thereto. All ratios of mixing will be given in parts by mass.

### Example 1

Materials listed below were mixed using a mixer, kneaded using a two-roll mill with the surface temperature respectively adjusted to 90° C. and 45° C., and then cooled and crushed, to prepare an epoxy resin composition. The obtained epoxy resin composition was evaluated by the methods below. Results are shown in Table 1.

Epoxy resin 1: biphenyl-type epoxy resin represented by the formula (3) (YX4000K, from Japan Epoxy Resin Co., Ltd., melting point=105° C., epoxy equivalent weight-185, having methyl groups for R⁴, R⁶, R⁹ and R¹¹, and hydrogen atoms for R⁵, R⁷, R⁸ and R¹⁰ the formula (3)): 7.1 parts by mass

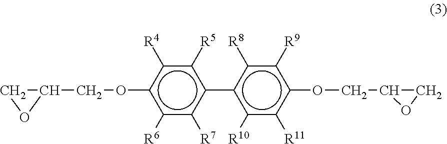

Phenol resin 1: multi-functional phenol resin represented by the formula (4) (HE910-20, fromAir Water Inc., softening point-88° C., hydroxy equivalent weight=101): 3.9 parts by mass

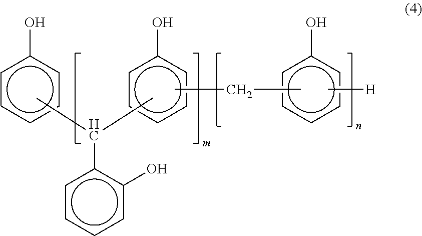

Curing accelerator: curing accelerator represented by the formula (7) below: 0.3 parts by mass

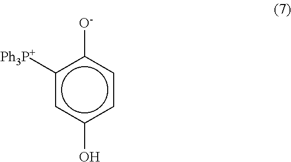

Fused spherical silica (average grain size=20 μm): 88.0 parts by mass

Silane coupling agent 1: silane coupling agent obtained by hydrolyzing a silane coupling agent represented by the formula (2) below (AZ-6137, from Nippon Unicar Co., Ltd.), and by poly-condensing the hydrolysate: 0.2 parts by mass

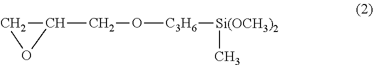

Mold releasing agent: glycerin trimontanate (Licolub (registered trademark) WE4, from Clariant Japan K.K.): 0.2 parts by mass

Carbon black (MA600, from Mitsubishi Chemical Corporation): 0.3 parts by mass

### Evaluation Methods

Spiral flow: The epoxy resin composition was injected into a die for measuring spiral flow, according to ANSI/ASTM D 3123-72 using a low pressure transfer molding machine (KTS-15, from Kohtaki Corpoartion), at a die temperature of 175° C., an injection pressure of 6.9 MPa, and a curing time of 120 seconds, and flow length was measured in centimeter.

Soldering resistance 1: A 352-pin BGA (a 0.56 mm thick bismaleimide-triazine resin/glass fabric reinforced substrate, with a package of 30 mm×30 mm in size, 1.17 mm thick) was molded using a low pressure transfer molding machine (Y Series, from TOWA Corporation), at a die temperature of 175° C., an injection pressure of 6.9 MPa, and a curing time of 2 minutes, and then cured at 175° C. for 4 hours, to thereby obtain samples. Ten thus-obtained packages were allowed to absorb moisture in an environment at 60° C., 60% RH for 120 hours, and then subjected to IR reflow at a peak temperature of 260° C. (held for 10 seconds at 255° C. or above). Separation between the polyimide film on the surface of the semiconductor element and the encapsulating resin was observed using a ultrasonic flaw detector (mi-scope10, from Hitachi Construction Machinery Co., Ltd.). Those causing the separation were judged as defective packages, and denoted as n/10, using the number n of defective packages.

Soldering resistance 2: Measured similarly to Soldering resistance 1, except that the time of moisture absorption was set to 168 hours.

The above-described soldering resistances 1 and 2 were evaluated using the semiconductor element shown below, having a 5 μm thick polyimide film formed over the entire surface.

Semiconductor element: 10 mm×10 mm in size, 0.35 mm thick.

Polyimide film: obtained by dealcoholizing a dehydrated condensate (polyimide precursor) formed between 2-hydroxyethyl methacrylate diester of 3,3′,4,4′-benzophenone tetracarboxylic acid and bis[4-(4-aminophenoxy)phenyl]sulfone.

Amount of warping of package: Amount of height-wise dislocation of ten each of the samples, molded similarly to the method described in the soldering resistance, were measured in the direction diagonally from the gate of each package, using a surface texture and contour measuring instrument (SURFCOM 408A, from Tokyo Seimitsu Co., Ltd.), and the largest value of dislocation in micrometer was determined as the amount of warping.

### Examples 2 to 10, and Comparative Examples 1 to 3

Epoxy resin compositions were prepared according to formulation listed in Table 1, similarly as described in Example 1, and similarly evaluated. Results are shown in Table 1.

Ingredients other than those used in Example 1 are listed below.

Epoxy resin 2: ortho cresol novolac-type epoxy resin (N660, from DIC Corporation, softening point-62° C., epoxy equivalent weight=210)

Phenol resin 2: phenol novolac resin (PR-HF-3, from Sumitomo Bakelite Co., Ltd., softening point=80° C., hydroxy equivalent weight=104)

Silane coupling agent 2: silane coupling agent (AZ-6137, from Nippon Unicar Co., Ltd.) represented by the formula (2) below:

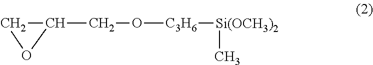

Silane coupling agent 3: silane coupling agent obtained by hydrolizing a silane coupling agent (A-187, from Nippon Unicar Co., Ltd.) represented by the formula (8) below, and then poly-condensing the hydrolysate.

Silane coupling agent 4: silane coupling agent (A-187, from Nippon Unicar Co., Ltd.) represented by the formula (8) below:

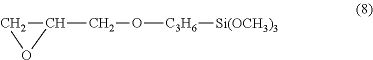

Silane coupling agent 5: silane coupling agent (A-186, from Nippon Unicar Co., Ltd.) represented by the formula (9) below:

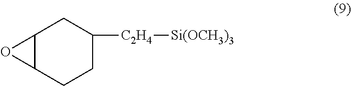

Silane coupling agent 6: silane coupling agent (KBM573, from Shin-Etsu Chemical Co., Ltd.) represented by the formula (10):

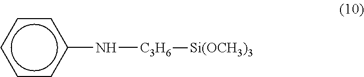

TABLE 1

| | Example | | | | | | | | | | Comparative | | |
|---|---|---|---|---|---|---|---|---|---|---|---|---|---|
| | 1 | 2 | 3 | 4 | 5 | 6 | 7 | 8 | 9 | 10 | 1 | 2 | 3 |
| Epoxy resin 1 | 7.1 | 7.2 | 6.8 | 7.1 | 7.1 | 7.1 | 7.1 | 7.1 | | 7.1 | 7.1 | | 7.1 |
| Epoxy resin 2 | | | | | | | | | 7.2 | | | 7.2 | |
| Phenol resin 1 | 3.9 | 3.9 | 3.6 | 3.9 | 3.9 | 3.9 | 3.9 | 3.9 | | | 3.9 | | |
| Phenol resin 2 | | | | | | | | | 3.8 | 3.9 | | 3.8 | 3.9 |
| Curing accelerator | 0.3 | 0.3 | 0.3 | 0.3 | 0.3 | 0.3 | 0.3 | 0.3 | 0.3 | 0.3 | 0.3 | 0.3 | 0.3 |
| Fused spherical silica | 88 | 88 | 88 | 88 | 88 | 88 | 88 | 88 | 88 | 88 | 88 | 88 | 88 |
| Silane coupling agent 1 | 0.2 | 0.1 | 0.8 | | | | | 0.15 | 0.2 | 0.2 | | | |
| Silane coupling agent 2 | | | | 0.2 | | | | | | | | | |
| Silane coupling agent 3 | | | | | 0.2 | | | | | | | | |
| Silane coupling agent 4 | | | | | | 0.2 | | | | | | | |
| Silane coupling agent 5 | | | | | | | 0.2 | | | | | | |
| Silane coupling agent 6 | | | | | | | | 0.05 | | | 0.2 | 0.2 | 0.2 |
| Mold releasing agent | 0.2 | 0.2 | 0.2 | 0.2 | 0.2 | 0.2 | 0.2 | 0.2 | 0.2 | 0.2 | 0.2 | 0.2 | 0.2 |
| Carbon black | 0.3 | 0.3 | 0.3 | 0.3 | 0.3 | 0.3 | 0.3 | 0.3 | 0.3 | 0.3 | 0.3 | 0.3 | 0.3 |
| Spiral flow [cm] | 140 | 145 | 130 | 135 | 140 | 135 | 135 | 145 | 70 | 105 | 135 | 110 | 120 |
| Soldering resistance 1 | 0/10 | 0/10 | 0/10 | 0/10 | 0/10 | 0/10 | 0/10 | 0/10 | 0/10 | 0/10 | 5/10 | 7/10 | 8/10 |
| Soldering resistance 2 | 0/10 | 0/10 | 0/10 | 3/10 | 2/10 | 3/10 | 3/10 | 0/10 | 5/10 | 5/10 | 10/10 | 10/10 | 10/10 |
| Amount of warping of | 70 | 70 | 60 | 70 | 70 | 70 | 70 | 70 | 100 | 130 | 70 | 100 | 130 |
| package [μm] | | | | | | | | | | | | | |

The epoxy resin compositions of Examples 1 to 10 includes the epoxy resin (A), the phenol resin (B), the curing accelerator (C), the inorganic filler (D), and the silane coupling agent (E) represented by the formula (1) and/or the hydrolytic condensate thereof. Species and amounts of the silane coupling agent (E) and/or the hydrolytic condensate thereof, and species of the epoxy resin (A) and the phenol resin (B) are listed in Table 1. All of the semiconductor devices encapsulated with the epoxy resin compositions of Examples 1 to 10 were found to cause no separation between the polyimide film on the surface of the semiconductor element and the epoxy resin composition under the conditions of the soldering resistance 1, proving good close adhesiveness. Examples 1 to 8, using epoxy resin 1 which is the biphenyl-type epoxy resin represented by the formula (3) as the epoxy resin (A), and using phenol resin 1 which is the multi-functional phenol resin represented by the formula (4) as the phenol resin (B), gave good results which are represented by less separation between the polyimide film on the surface of the semiconductor element and the encapsulating resin, and only small amounts of warping of packages, even under the conditions of the soldering resistance 2. In addition, Examples 1 to 3 and 8, using epoxy resin 1 as the epoxy resin (A), phenol resin 1 as the phenol resin (B), and silane coupling agent 1, which is a silane coupling agent obtained by hydrolyzing the silane coupling agent represented by the formula (2) and poly-condensing the hydrolysate, as the silane coupling agent (E) and/or the hydrolytic condensate thereof, were found to give excellent effects, causing no separation between the polyimide film on the surface of the semiconductor element and the encapsulating resin, even under the conditions of the soldering resistance 2, irrespective of the amount of mixing of the silane coupling agent 1, and presence or absence of other silane coupling agents.

In contrast, the semiconductor devices of Comparative Examples 1 to 3, using the epoxy resin compositions which contain neither silane coupling agent (E) represented by the formula (1) nor the hydrolytic condensate thereof, were found to show large numbers of separation between the polyimide film on the surface of the semiconductor element and the encapsulating resin, under conditions of both of the soldering resistances 1 and 2, proving poor close adhesiveness.

1. A semiconductor device configured by encapsulating a semiconductor element, partially or entirely covered with a polyimide, using an epoxy resin composition for encapsulating semiconductor device which contains an epoxy resin (A), a phenol resin (B), a curing accelerator (C), an inorganic filler (D), and a silane coupling agent (E) represented by the formula (1): 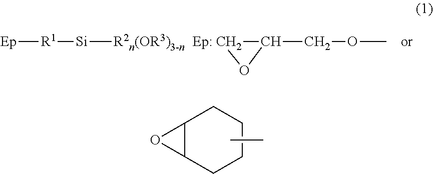
(in the formula (1), each of R¹, R² and R³ represents a C₁₋₄ hydrocarbon group, all of them may be the same or different from each other, and n represents an integer from 0 to 2), and/or a hydrolytic condensate thereof.

2. The semiconductor device according to claim 1,
wherein the silane coupling agent (E) and/or the hydrolytic condensate thereof is a silane coupling agent represented by the formula (2) below: 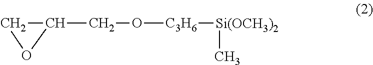
and/or a hydrolytic condensate thereof.

3. The semiconductor device according to claim 1,
wherein ratio of the silane coupling agent (E) and/or the hydrolytic condensate thereof accounts for 0.01 to 1.0% by mass of the whole epoxy composition for encapsulating semiconductor device.

4. The semiconductor device according to claim 1,
wherein the epoxy resin (A) contains an epoxy resin represented by the formula (3) below: 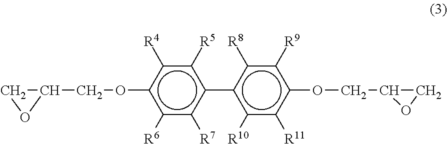
(in the formula (3), each of R⁴ to R¹¹ is selected from a hydrogen atom and C₁₋₄ alkyl group, all of them may be the same or different from each other).

5. The semiconductor device according to claim 1,
wherein the phenol resin (B) contains a phenol resin represented by the formula (4): 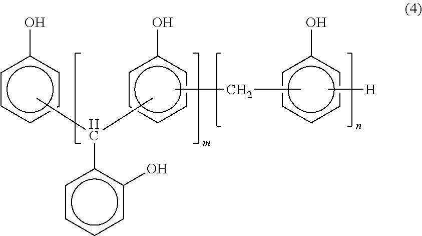
(in the formula (4), m represents an integer from 1 to 5, and n represents an integer from 0 to 5).

6. The semiconductor device according to claim 1,
wherein the polyimide is obtained by dealcoholization of a polyimide precursor represented by the formula (5): 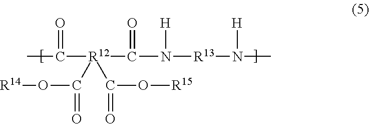
(in the formula (5), R¹² is an organic group having at least two carbon atoms, R¹³ is an organic group having at least two carbon atoms, each of R¹⁴ and R¹⁵ is an organic group having at least one double bond, all of them may be the same or different from each other).

7. The semiconductor device according to claim 6,
wherein R¹², R¹³, R¹⁴ and R¹⁵ of the polyimide precursor represented by the formula (5) are groups represented by the formula (6) below:

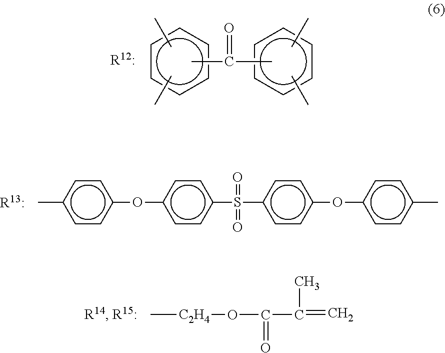

8. The semiconductor device according to claim 1 configured as an area mounting-type semiconductor device, having the semiconductor element mounted on one surface of a substrate, and only the surface of the substrate having the semiconductor element mounted thereon being encapsulated with the epoxy resin composition for encapsulating semiconductor device.

9. The semiconductor device according to claim 1 configured as a board-on-chip type semiconductor device, having the semiconductor element mounted on one surface of a substrate having an opening, and the surface of substrate having the semiconductor element mounted thereon and the opening being encapsulated with the epoxy resin composition for encapsulating semiconductor device.
